(19) United States
(12) Patent Application Publication
(10) Pub. No.: US 2011/0260036 A1
(43) Pub. Date: Oct. 27, 2011

(54) Temporally- And Spatially-Resolved Single Photon Counting Using Compressive Sensing For Debug Of Integrated Circuits, Lidar And Other Applications

(76) Inventors: Richard G. Baraniuk, (US); Kevin F. Kelly, Houston, TX (US); Gary L. Woods, Houston, TX (US)

(21) Appl. No.: 13/032,616

(22) Filed: Feb. 22, 2011

Related U.S. Application Data
(60) Provisional application No. 61/306,817, filed on Feb. 22, 2010.

(51) Int. Cl. H01L 27/146

(52) U.S. Cl. 250/208.1

(57) ABSTRACT

A method for photon counting including the steps of collecting light emitted or reflected/scattered from an object; imaging the object onto a spatial light modulator, applying a series of pseudo-random modulation patterns to the SLM according to standard compressive-sensing theory, collecting the modulated light onto a photon-counting detector, recording the number of photons received for each pattern (by photon counting) and optionally the time of arrival of the received photons, and recovering the spatial distribution of the received photons by the algorithms of compressive sensing (CS).

### CROSS-REFERENCE TO RELATED APPLICATIONS

The present application claims the benefit of the filing date of U.S. Provisional Patent Application Ser. No. 61/306,817 entitled “Temporally- And Spatially-Resolved Single Photon Counting Using Compressive Sensing For Use In Integrated Circuit Debug And Failure Analysis” and filed by the present inventors on Feb. 22, 2010.

The aforementioned provisional patent application is hereby incorporated by reference in its entirety.

### STATEMENT REGARDING FEDERALLY SPONSORED RESEARCH OR DEVELOPMENT

None.

### BACKGROUND OF THE INVENTION

1. Field of the Invention

The present invention relates to systems and methods for integrated circuit debug and failure analysis, and more specifically, to systems and methods for temporally- and spatially-resolved single photon counting using compressive sensing.

2. Brief Description of the Related Art

A theory known as Compressive Sensing (CS) has emerged that offers hope for directly acquiring a compressed digital representation of a signal without first sampling that signal. See Candès, E., Romberg, J., Tao, T., “Robust uncertainty principles: Exact signal reconstruction from highly incomplete frequency information,” IEEE Trans. Inform. Theory 52 (2006) 489-509; David Donoho, “Compressed Sensing,” IEEE Transactions on Information Theory, Volume 52, Issue 4, April 2006, Pages: 1289-1306; and Candès, E., Tao, T., “Near optimal signal recovery from random projections and universal encoding strategies,” (2004) Preprint. Various schemes for directly applying this new theory in image acquisition have been presented in patent applications and in the literature, but those systems and methods typically employ a single modulator scheme. For example, in U.S. Patent Application Publication No. 2006239336, entitled “Method and Apparatus for Compressive Imaging Device,” the inventors disclosed a system and method for a new digital image/video camera that directly acquires random projections without first collecting the N pixels/voxels. Due to this unique measurement approach, it had the ability to obtain an image with a single detection element while measuring the image far fewer times than the number of pixels/voxels. The image could be reconstructed, exactly or approximately, from these random projections by using a model, in essence to find the best or most likely image (in some metric) among all possible images that could have given rise to those same measurements. A small number of detectors, even a single detector, could be used. Thus, the camera could be adapted to image at wavelengths of electromagnetic radiation that were impossible with conventional CCD and CMOS imagers. This feature was deemed to be particularly advantageous, because in some cases the usage of many detectors is impossible or impractical, whereas the usage of a small number of detectors, or even a single detector, may become feasible using compressive imaging.

CS builds on the ground-breaking work of Candès, Romberg, and Tao (see E. Candès, J. Romberg, and T. Tao, “Robust uncertainty principles: Exact signal reconstruction from highly incomplete frequency information,” IEEE Trans. Inf. Theory, vol. 52, no. 2, pp. 489-509, 2006) and Donoho (see D. Donoho, “Compressed sensing,” IEEE Trans. Inf. Theory, vol. 52, no. 4, pp. 1289-1306, 2006), who showed that if a signal has a sparse representation in one basis then it can be recovered from a small number of projections onto a second basis that is incoherent with the first. Roughly speaking, incoherence means that no element of one basis has a sparse representation in terms of the other basis. This notion has a variety of formalizations in the CS literature (see E. Candès, J. Romberg, and T. Tao, “Robust uncertainty principles: Exact signal reconstruction from highly incomplete frequency information,” IEEE Trans. Inf. Theory, vol. 52, no. 2, pp. 489-509, 2006; D. Donoho, “Compressed sensing,” IEEE Trans. Inf. Theory, vol. 52, no. 4, pp. 1289-1306, 2006; E. Candès and T. Tao, “Near optimal signal recovery from random projections and universal encoding strategies,” August 2004, Preprint and J. Tropp and A. C. Gilbert, “Signal recovery from partial information via orthogonal matching pursuit,” April 2005, Preprint).

In fact, for an N-sample signal that is K-sparse, only K+1 projections of the signal onto the incoherent basis are required to reconstruct the signal with high probability. By K-sparse, we mean that the signal can be written as a sum of K basis functions from some known basis. Unfortunately, this requires a combinatorial search, which is prohibitively complex. Candès et al. (see E. Candès, J. Romberg, and T. Tao, “Robust uncertainty principles: Exact signal reconstruction from highly incomplete frequency information,” IEEE Trans. Inf. Theory, vol. 52, no. 2, pp. 489-509, 2006) and Donoho (see D. Donoho, “Compressed sensing,” IEEE Trans. Inf. Theory, vol. 52, no. 4, pp. 1289-1306, 2006) have recently proposed tractable recovery procedures based on linear programming, demonstrating the remarkable property that such procedures provide the same result as the combinatorial search as long as cK projections are used to reconstruct the signal (typically c≈3 or 4) (see E. Candès and T. Tao, “Error correction via linear programming,” Found. of Comp. Math., 2005, Submitted; D. Donoho and J. Tanner, “Neighborliness of randomly projected simplices in high dimensions,” March 2005, Preprint and D. Donoho, “High-dimensional centrally symmetric polytopes with neighborliness proportional to dimension,” January 2005, Preprint). Iterative greedy algorithms have also been proposed (see J. Tropp, A. C. Gilbert, and M. J. Strauss, “Simultaneous sparse approximation via greedy pursuit,” in IEEE 2005 Int. Conf. Acoustics, Speech, Signal Processing (ICASSP), Philadelphia, March 2005; M. F. Duarte, M. B. Wakin, and R. G. Baraniuk, “Fast reconstruction of piecewise smooth signals from random projections,” in Online Proc. Workshop on Signal Processing with Adaptative Sparse Structured Representations (SPARS), Rennes, France, November 2005 and C. La and M. N. Do, “Signal reconstruction using sparse tree representation,” in Proc. Wavelets XI at SPIE Optics and Photonics, San Diego, August 2005), allowing even faster reconstruction at the expense of slightly more measurements.

In U.S. Pat. No. 7,271,747, entitled “Method and Apparatus for Distributed Compressed Sensing,” the inventors disclosed, among other embodiments, a method for approximating a plurality of digital signals or images using compressed sensing. In a scheme where a common component x, of said plurality of digital signals or images an innovative component xᵢ of each of said plurality of digital signals each are represented as a vector with m entries, the method comprises the steps of making a measurement y_{c}, where y_{c} comprises a vector with only nᵢ entries, where nᵢ is less than m, making a measurement yᵢ for each of said correlated digital signals, where yᵢ comprises a vector with only nᵢ entries, where nᵢ is less than m, and from each said innovation components yᵢ, producing an approximate reconstruction of each m-vector xᵢ using said common component y_{c} and said innovative component yᵢ.

In many applications it is necessary to acquire very faint optical signals. The highest-performing detectors for this purpose are photon-counting (PC) detectors, which include photomultiplier tubes (PMTs) and solid state photon counters (SSPCs) such as avalanche photodiodes (APDs). Photon counters produce a voltage or current pulse for each measured photon. These pulses are measured by standard electronic circuits, thus providing a count of the number of incident photons. The technique of using photon-counting detectors is called single-photon counting. Photon-counting devices also provide inherent temporal resolution of the incident photons (typically ns to ps resolution). The technique of time-correlated single photon counting (TCSPC) takes advantage of this resolution to record the arrival time of each photon with respect to some external trigger.

Most photon counting devices, such as standard PMTS and APDs, are incapable of providing spatial as well as temporal resolution. Spatially-resolved photon counters do exist, for instance the microchannel-plate PMT inside the Hamamatsu TriPhemos system (http://sales.hamamatsu.com/en/products/system-division/semiconductor-industry/failure-analysis/part-triphemos.php) or the MEPSICRON-II microchannel-plate PMT sold by Quantar Technology (http://quantar.com/pages/QTI/optical.htm). Such spatially-resolved photon counters are very expensive and typically offer reasonable but not excellent temporal resolution (100-150 ps).

To obtain spatially-resolved PC data, there are three main techniques in the current state of the art. The first is to use a single-element PC detector which is optically scanned across the field of view by means of, for example, mirrors. (Essentially a raster scan technique which we will term RS.) If there are N pixels in the image and an average of P photons per pixel in time T, then the recovered signal to noise ratio (SNR) measured as the square of the image amplitude, scales as P in an acquisition time of N*T, assuming that the noise is dominated by the poisson (shot) noise of the photons, which is commonly though not always the case. By contrast, if the detector were staring at a single pixel for the entire time N*T then the SNR would be of order N*P, in that one pixel, which could easily be several orders of magnitude higher. Thus there is a large SNR penalty of order N incurred by raster-scanning. An array detector would not incur this penalty, but as described above such detectors are often not available, or are too costly, or do not have sufficient performance for the application. An additional problem with RS is the slow speed of acquisition—a 1 MPix image could easily take several seconds to acquire due to the limited speed of the scanning mirrors. See, for example, Tague et al., U.S. Pat. No. 5,923,036, Kimura et al. U.S. Pat. No. 7,326,900, Brady et al. U.S. Pat. No. 7,432,823, Gentry et al. U.S. Pat. No. 6,996,292.

The second method of providing spatial resolution is to use either structured illumination or structured detection of the field of view along with a single-element PC device. We shall term this method “basis scan” (BS). In this technique one employs an external spatial light modulator (SLM), composed of N pixels, either on the illumination source of the field of view, or on the light received from the field of view by the imaging system at a secondary image plane within the instrument. In either case, the light is ultimately collected into a single-element PC detector. If N pixels are to be acquired in the image, then N unique and orthogonal patterns must be applied to the SLM. The set of N measurements is inverted to obtain an N-pixel image. In the shot-noise limit, the recovered image has an SNR that scales as P/2, nearly the same as the raster-scanning technique in the shot-noise limit. In the dark-noise limit the BS technique is significantly superior to the RS technique as far more signal—from N/2 pixels instead of just from 1 pixel—is acquired by the detector in BS compared to RS. One disadvantage of the BS technique is that it is often limited by the speed of the SLM—e.g. a digital micromirror device can only produce on the order of 50,000 patterns per second, meaning that to acquire 1 Mpix image would require about 20 seconds, which can be too long for many applications (including video processing.)

The third technique is to use a PC detector that has spatial resolution. One such device is the electron-multiplying CCD (EM-CCD) which can achieve near photon-counting performance in an array format (though with limited temporal resolution). For wavelengths which are visible to silicon detectors (shorter than 1 um) the EM-CCD is often an attractive choice. The MCP-PMTs as described above are also used to provide spatially resolved SPC data.

Thus there is a need for a device and method for producing spatially- and temporally-resolved single photon counting with reasonable cost and performance and with higher throughput than is currently available in the state of the art.

### SUMMARY OF THE INVENTION

The present invention will improve the performance of instruments that acquire spatially- and temporally-resolved photon-counting data. The performance gain comes from the compressive sensing techniques described in the Background section above, which allow faster acquisition times and/or higher signal to noise ratios compared to the state of the art (BS or RS). The signal to noise ratio at each pixel will be approximately the same at every pixel as in the original single-element detector. (The average photon counts will be reduced by a factor of 2 at every pixel due to the 50% duty cycle of the spatial light modulator.) The technique relies on an SLM to provide spatial resolution and a single-element PC detector, along with inversion of the CS data. Using CS it is possible to acquire a number M, which is far fewer then N, measurements which provides a speed up or SNR improvement. A typical ratio of M/N for still images is about 10% for high quality reconstruction, representing a 10× improvement over RS. The useful M/N ratio should decrease further in the case where the data is also temporally-resolved, as the data cube (2 spatial dimensions and 1 temporal dimension) is much larger than in the 2D case, and sparsity should yield an even greater advantage for CS over BS. The present invention may employ the CS reconstruction techniques disclosed in Baraniuk et al., U.S. Pat. No. 7,271,747. Some specific applications include: failure analysis and debug of integrated circuits and LIDAR (Laser Detection and Ranging).

This present invention provides novel variations and improvements on the same method of CS image reconstruction as disclosed in Baraniuk et al. U.S. Pat. No. 7,271,747. The novel variations and improvements include, but are not limited to, the following: first, a photon-counting detector is used for data acquisition rather than a photodiode; and second, the acquired data has a temporal component as well as 2D spatial components.

In a preferred embodiment, the present invention is a method for photon counting including the steps of collecting light emitted or reflected/scattered from an object; imaging the object onto a spatial light modulator (SLM), applying a series of pseudo-random modulation patterns to the SLM according to standard compressive-sensing theory, collecting the modulated light onto a photon-counting detector, recording the number of photons received for each pattern (by photon counting) and optionally the time of arrival of the received photons, and recovering the spatial distribution of the received photons within one or multiple time intervals by the algorithms of compressive sensing (CS). The spatial light modulator may comprise, for example, a digital micromirror device or other devices such as are disclosed in co-pending PCT Application Serial No. PCT/US2010/059343, which is hereby incorporated by reference in its entirety.

Another realization from such a measurement scheme is that the acquired information is a three dimensional data cube with two spatial and one temporal axis allowing the strength of the optical signal at any given point in space to be correlated in time. In this embodiment the temporal resolution comes from the time-scale of the detector. The compressed information acquired in this manner is similar to the compressed hyperspectral imager discussed in U.S. Patent Application Publication No. 2006239336, entitled “Method and Apparatus for Compressive Imaging Device,” when the single photodetector is replaced with a spectrometer. In the present invention however, the 3^{rd} axis of the data cube is temporal rather than spectral. Accordingly the method uses time-correlated single photon counting detectors but does not require a spectrometer or other dispersive optical element.

Another realization from such a measurement scheme is that subframe temporal information from the point of the view of the detector can be achieved by temporally changing the spatial modulator on a timescale faster that the integrated measurement rate of the detector. While the information acquired at the detector results in a blurred image on the slower time scale due to events changing on a faster time scale, such information is uniquely encoded by the spatial light modulator on the faster time scale. This information can be decoded using L1 mathematics in manner similar to Baraniuk et al. compressed sensing analog-to-digital conversion patent to realize a denser set of measurements in the three dimensional data cube.

In a preferred embodiment, the present invention is a method for photon counting. The method comprises the steps of collecting light emitted or reflected/scattered from an object, imaging the object onto a spatial light modulator (SLM), applying a series of pseudo-random modulation patterns to the SLM according to standard compressive-sensing theory, collecting the modulated light onto a photon-counting detector, recording the number and time of arrival of the photons received for each pattern (by time-resolved photon counting), and recovering the spatial and temporal distribution of the received photons over one or more intervals of the total time range spanned by the measurements, by the algorithms of compressive sensing (CS). The spatial light modulator may comprise a digital micromirror device.

In another preferred embodiment, the present invention is a method for photon counting based upon inner products. The method comprises the steps of modulating an incident light field corresponding to an image by a series of patterns with a spatial light modulator, optically computing inner products between the light field of the image and the series of patterns with an encoder, recording the number of photons received for each pattern by photon counting, and recovering the spatial distribution of the received photons based upon the inner products from the encoder, wherein the recovering step is based on at least one of a Greedy reconstruction algorithm, Matching Pursuit, Orthogonal Matching Pursuit, Basis Pursuit, group testing, LASSO, LARS, expectation-maximization, Bayesian estimation algorithm, belief propagation, wavelet-structure exploiting algorithm, Sudocode reconstruction, reconstruction based on manifolds, l₁ reconstruction, l₀ reconstruction, and l₂ reconstruction.

In still another preferred embodiment, the present invention is a method for decomposing the integrated temporal signature of the arriving photons to a resolution finer than the integration time of the detector and is instead resolved to the temporal frame rate of the modulator.

Still other aspects, features, and advantages of the present invention are readily apparent from the following detailed description, simply by illustrating a preferable embodiments and implementations. The present invention is also capable of other and different embodiments and its several details can be modified in various obvious respects, all without departing from the spirit and scope of the present invention. Accordingly, the drawings and descriptions are to be regarded as illustrative in nature, and not as restrictive. Additional objects and advantages of the invention will be set forth in part in the description which follows and in part will be obvious from the description, or may be learned by practice of the invention.

### BRIEF DESCRIPTION OF THE DRAWINGS

For a more complete understanding of the present invention and the advantages thereof, reference is now made to the following description and the accompanying drawings, in which:

FIG. 1 is a diagram of a preferred embodiment of the present invention.

### DETAILED DESCRIPTION OF THE PREFERRED EMBODIMENTS

In a preferred embodiment of the present invention, compressive sensing (CS) is used via a spatial light modulator to obtain spatial and temporal data from photon-counting measurements. The technique could be applied to LIDAR as well as to debug and failure analysis of integrated circuits. Instead of using an imaging photomultiplier tube (which have very low quantum efficiency and/or high dark counts in the spectral range of interest) one can use a single-element photon-counting device in conjunction with a spatial light modulator (SLM).

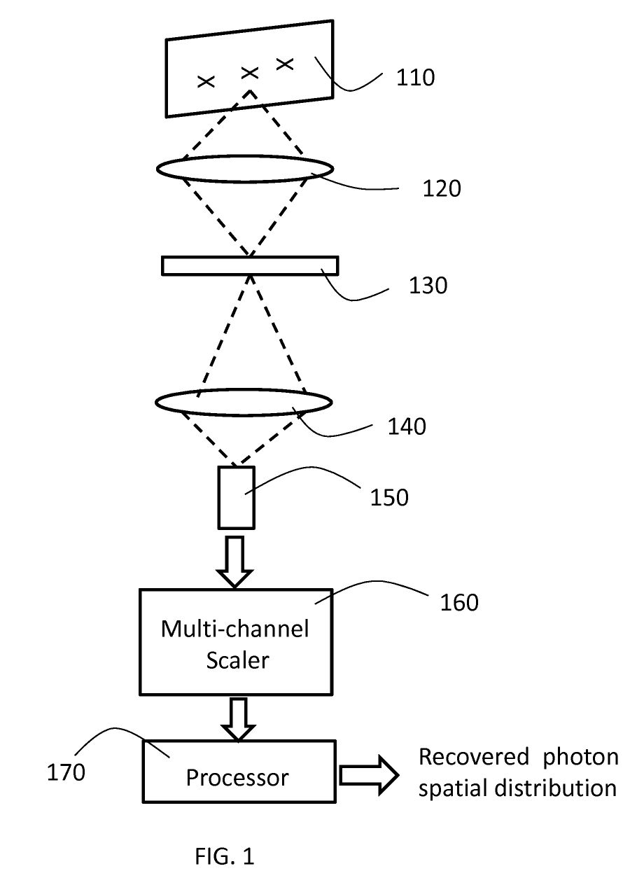

A setup of a preferred embodiment of the present invention, as shown in FIG. 1, has an object or scene 110, a lens or light collector 120, a spatial light modulator, or SLM, 130, a light collector or lens 140, and a single element detector or time resolved photon counter 150. The object or scene 110 may be illuminated, such as by a pulsed laser light source, or may be self-luminous, e.g., hot electron luminescence in semiconductor integrated circuits. The spatial light modulator 130 is used to obtain photon-counting measurements from a large (multi-pixel) area 110, for example on an integrated circuit, using a single-element photon counting device 150.

The spatial light modulator 130 may be, for example, a digital micromirror device (DMD). A DMD may comprise an array of electrostatically actuated micromirrors where each mirror of the array is suspended above an individual SRAM cell. Each mirror rotates about a hinge and can be positioned in one of two states (for example, +12 degrees and −12 degrees from horizontal); thus light falling on the DMD may be reflected in two directions depending on the orientation of the mirrors.

The system, however, does not have to rely on reflecting light off a digital micromirror device as in FIG. 1. The concept is that it can be based on any system that is capable of modulating the incident lightfield x (be it by transmission, reflection, or other means) by some series of patterns φₘ and then integrating this modulated lightfield at a number of points to compute the inner products y(m)=<x,φₘ^{T}> between the light field and the series of patterns (so-called “incoherent projections” y=Φx). From these inner products the present invention can recover the original signal (with fewer inner products than the number of pixels that are ultimately reconstructed). Examples of systems that can modulate lightfields include digital micromirror devices, LCD shutter arrays (as in an LCD laptop projector), physically moving shutter arrays, any material that can be made more and less transparent to the lightfield of interest at different points in space, etc.

The SLM, for example, may apply variable patterns according to compressed sensing theory. Compressive sensing (CS) algorithms, for example applied by a processor, are used to reconstruct photon counts vs. time in a 3-dimensional data cube (2d spatial and 1d temporal). A trigger signal or timing reference may be applied. As an example, the present techniques may be used for measuring light emission from transistors in integrated circuits.

In a preferred embodiment using a DMD, an incident light field corresponding to the object or scene 110 passes through the lens or light collecting or focusing element 120. The light field is then reflected off the DMD array 130 whose mirror orientations are modulated in a pseudorandom pattern sequence supplied by a random number generator or generators. The modulated light then passes through a re-imaging element or lens 140 and onto the single element photon counting device 150. The number and arrival times of photons from the single element photon counting device 150 may then be quantized by a standard electronic readout unit such as a multichannel scaler 160. The bitstream produced is then communicated to a reconstruction algorithm, for example in a processor 170, which yields an output or recovered image of N spatial pixels from substantially fewer than N measurements.

The steps in a method according to a preferred embodiment of the present invention may be as follows: (1) collecting light emitted or reflected/scattered from an object; (2) imaging the object onto a spatial light modulator (such as a digital micromirror device (DMD)); (3) applying a series of pseudo-random modulation patterns to the SLM according to standard compressive-sensing theory; (4) collecting the modulated light onto a photon-counting detector; (5) recording the number of photons received for each pattern (by photon counting) and the time of arrival of the received photons; and (6) recovering the spatial distribution, with N pixels of resolution, of the received photons by the algorithms of compressive sensing (CS) from fewer than N measurements.

In other embodiments, light can be emitted from the object (as in luminescence) or can be reflected/scattered light as from a laser beam.

In operation the present invention uses for random measurements a digital micromirror array or other SLM to spatially modulate an incident image and reflecting the result to a lens, which focuses the light to a photon counter for measurement. Mathematically, these measurements correspond to inner products of the incident image with a sequence of pseudorandom patterns. For an image model the system assumes sparsity or compressibility; that is, that there exists some basis, frame, or dictionary (possibly unknown at the camera) in which the image has a concise representation. For reconstruction, this system and method uses the above model (sparsity/compressibility) and some recovery algorithm (based on optimization, greedy, iterative, or other algorithms) to find the sparsest or most compressible or most likely image that explains the obtained measurements. The use of sparsity for signal modeling and recovery from incomplete information are the crux of the recent theory of Compressive Sensing (CS).

Compressive Sensing (CS) builds upon a core tenet of signal processing and information theory: that signals, images, and other data often contain some type of structure that enables intelligent representation and processing. Current state-of-the-art compression algorithms employ a decorrelating transform to compact a correlated signal's energy into just a few essential coefficients. Such transform coders exploit the fact that many signals have a sparse representation in terms of some basis Ψ, meaning that a small number K of adaptively chosen transform coefficients can be transmitted or stored rather than N signal samples, where K<N. Mathematically, we wish to acquire an N-sample signal/image/video x for which a basis or (tight) frame Ψ=[ψ₁, . . . , ψ_{N}] (see S. Mallat, A Wavelet Tour of Signal Processing. San Diego, Calif., USA: Academic Press, 1999) provides a K-sparse representation

$$x = {\sum }_{i = 1}^{k} {θ}_{{n}_{i}} {ψ}_{{n}_{i}} ,$$

where {nᵢ} are the vector indices, each nᵢ points to one of the elements of the basis or tight frame, and {θᵢ} are the vector coefficients. For example, smooth images are sparse in the Fourier basis, and piecewise smooth images are sparse in a wavelet basis; the commercial coding standards JPEG and JPEG2000 and various video coding methods directly exploit this sparsity (see Secker, A., Taubman, D. S., “Highly scalable video compression with scalable motion coding,” IEEE Trans. Image Processing 13 (2004) 1029-1041). For more information on Fourier, wavelet, Gabor, and curvelet bases and frames and wedgelets, see (S. Mallat, A Wavelet Tour of Signal Processing. San Diego, Calif., USA: Academic Press, 1999; E. Candès and D. Donoho, “Curvelets—A Surprisingly Effective Nonadaptive Representation for Objects with Edges,” Curves and Surfaces, L. L. Schumaker et al. (eds), Vanderbilt University Press, Nashville, Tenn.; D. Donoho, “Wedgelets: Nearly Minimax Estimation of Edges,” Technical Report, Department of Statistics, Stanford University, 1997).

The standard procedure for transform coding of sparse signals is to (i) acquire the full N-sample signal x; (ii) compute the complete set {θ(n)} of transform coefficients θ(i)=<x, ψ(i)>, where [symbol] [symbol] denotes the inner product, θ(i) denotes the i'th coefficient, and ψ(i) denotes the i'th basis vector (i'th column of the matrix Ψ); (iii) locate the K largest, significant coefficients and discard the (many) small coefficients; and (iv) encode the values and locations of the largest coefficients. In cases where N is large and K is small, this procedure is quite inefficient. Much of the output of the analog-to-digital conversion process ends up being discarded (though it is not known a priori which pieces are needed).

The recent theory of Compressive Sensing introduced by Candès, Romberg, and Tao and Donoho referenced above demonstrates that a signal that is K-sparse in one basis (call it the sparsity basis) can be recovered from cK nonadaptive linear projections onto a second basis (call it the measurement basis) that is incoherent with the first, where c is a small overmeasuring constant. While the measurement process is linear, the reconstruction process is decidedly nonlinear.

In CS, we do not measure or encode the K significant θ(n) directly. Rather, we measure and encode M<N projections y(m)=<x,φₘ^{T}> of the signal onto a second set of basis functions, where φₘ^{T} denotes the transpose of φₘ. In matrix notation, we measure

y=Φx, (1)

where y is an M×1 column vector, and the measurement basis matrix Φ is M×N with the m'th row the basis vector φₘ. Since M<N, recovery of the signal x from the measurements y is ill-posed in general; however the additional assumption of signal sparsity makes recovery possible and practical. Note that using M<N is the preferred embodiment, but one may also take a larger number of measurements (M=N or M>N).

The CS theory tells us that when certain conditions hold, namely that the basis cannot sparsely represent the elements of the sparsity-inducing basis (a condition known as incoherence of the two bases) and the number of measurements M is large enough, then it is indeed possible to recover the set of large {θ(n)} (and thus the signal x) from a similarly sized set of measurements {y(m)}. This incoherence property holds for many pairs of bases, including for example, delta spikes and the sine waves of the Fourier basis, or the Fourier basis and wavelets. Significantly, this incoherence also holds with high probability between an arbitrary fixed basis and a randomly generated one (consisting of i.i.d. Gaussian or Bernoulli/Rademacher ±1 vectors). Signals that are sparsely represented in frames or unions of bases can be recovered from incoherent measurements in the same fashion.

We call the rows of Φ the measurement basis, the columns of Ψ the sparsity basis or sparsity inducing basis, and the columns of V=ΦΨ=[V₁, . . . , V_{N}] the holographic basis. Note that the CS framework can be extended to frames and more general dictionaries of vectors.

The recovery of the sparse set of significant coefficients {θ(n)} can be achieved using optimization or other algorithms by searching for the signal with l₀-sparsest coefficients {θ(n)} that agrees with the M observed measurements in y (recall that typically M<N). That is, we solve the optimization problem

θᵣ=argmin∥θ∥₀ such that y=ΦΨθ.

The l₀ norm ∥θ∥₀ counts the nonzero entries in the vector θ; hence it is a measure of the degree of sparsity, with more sparse vectors having smaller l₀ norm.

Unfortunately, solving this optimization problem is prohibitively complex and is believed to be NP-hard (see Candès, E., Tao, T., “Error correction via linear programming,” (2005) Preprint). The practical revelation that supports the new CS theory is that it is not necessary to solve the l₁-minimization problem to recover the set of significant {θ(n)}. In fact, a much easier problem yields an equivalent solution (thanks again to the incoherency of the bases); we need only solve for the l₁-sparsest coefficients θ that agree with the measurements y

θᵣ=argmin∥θ∥₁ such that y=ΦΨθ. (2)

The optimization problem (2), also known as Basis Pursuit (see Chen, S., Donoho, D., Saunders, M., “Atomic decomposition by basis pursuit,” SIAM J. on Sci. Comp. 20 (1998) 33-61), is significantly more approachable and can be solved with traditional linear programming techniques whose computational complexities are polynomial in N. Although only K+1 measurements are required to recover sparse signals via l₀ optimization, one typically requires M˜cK measurements for Basis Pursuit with an overmeasuring factor c>1.

We use the notation c to describe the overmeasuring/oversampling constant required in various settings and note the following approximation: The constant c satisfies c≈log 2 (1+N/K).

While reconstruction based on linear programming is one preferred embodiment, any reconstruction approach can be used in the present invention. Other examples include the (potentially more efficient) iterative Orthogonal Matching Pursuit (OMP) (see Tropp, J., Gilbert, A. C., “Signal recovery from partial information via orthogonal matching pursuit,” (2005) Preprint), matching pursuit (MP) (see Mallat, S. and Zhang, Z., “Matching Pursuit with Time Frequency Dictionaries”, (1993) IEEE Trans. Signal Processing 41(12): 3397-3415), tree matching pursuit (TMP) (see Duarte, M. F., Wakin, M. B., Baraniuk, R. G., “Fast reconstruction of piecewise smooth signals from random projections,” Proc. SPARS05, Rennes, France (2005)) algorithms, group testing (see Cormode, G., Muthukrishnan, S., “Towards an algorithmic theory of compressed sensing,” DIMACS Tech. Report 2005-40 (2005), Sudocodes (see U.S. Provisional Application Ser. No. 60/759,394 entitled “Sudocodes: Efficient Compressive Sampling Algorithms for Sparse Signals,” and filed on Jan. 16, 2006), or statistical techniques such as Belief Propagation, (see Pearl, J., “Fusion, propagation, and structuring in belief networks”, (1986) Artificial Intelligence, 29(3): 241-288), LASSO (see Tibshirani, R., “Regression shrinkage and selection via the lasso”, (1996) J. Royal. Statist. Soc B., 58(1): 267-288), LARS (see Efron, B., Hastie, T., Johnstone, I., Tibshirani, R., “Least Angle Regression”, (2004) Ann. Statist. 32(2): 407-499), Basis Pursuit with Denoising (see Chen, X., Donoho, D., Saunders, M., “Atomic Decomposition by Basis Pursuit”, (1999), SIAM Journal on Scientific Computing 20(1): 33-61), expectation-maximization (see Dempster, Laird, N., Rubin, D., “Maximum likelihood from incomplete data via the EM algorithm”, (1997) Journal of the Royal Statistical Society, Series B, 39(1): 1-38), and so on. These methods have also been shown to perform well on compressible signals, which are not exactly K-sparse but are well approximated by a K-term representation. Such a model is more realistic in practice.

Reconstruction can also be based on other signal models, such as manifolds (see Wakin, M, and Baraniuk, R., “Random Projections of Signal Manifolds” IEEE ICASSP 2006, May 2006, to appear). Manifold models are completely different from sparse or compressible models. Reconstruction algorithms in this case are not necessarily based on sparsity in some basis/frame, yet signals/images can be measured using the systems described here.

The foregoing description of the preferred embodiment of the invention has been presented for purposes of illustration and description. It is not intended to be exhaustive or to limit the invention to the precise form disclosed, and modifications and variations are possible in light of the above teachings or may be acquired from practice of the invention. The embodiment was chosen and described in order to explain the principles of the invention and its practical application to enable one skilled in the art to utilize the invention in various embodiments as are suited to the particular use contemplated. It is intended that the scope of the invention be defined by the claims appended hereto, and their equivalents. The entirety of each of the aforementioned documents is incorporated by reference herein.

What is claimed is:

1. A method for imaging comprising the steps of:
collecting light emitted or reflected/scattered from an object;
imaging the object onto a spatial light modulator;
applying a series of pseudo-random modulation patterns to the spatial light modulator according to standard compressive-sensing theory;
collecting the modulated light onto a photon-counting detector;
recording the number of photons received for each pattern (by photon counting); and
recovering the spatial distribution of the received photons by the algorithms of compressive sensing (CS).

2. A method for photon counting according to claim 1, where said spatial light modulator comprises a digital micromirror device.

3. A method for counting photons according to claim 1, wherein the step of recording further comprises recording the time of arrival of the received photons and subsequently generating a complete three-dimensional data cube encompassing two spatial dimensions plus one temporal dimension.

4. A method for counting photons according to claim 1, wherein the step of said photon detector provides time-correlated photon counts.

5. A method for counting photons according to claim 1, wherein the step of recovering further comprises recovering temporal information.

6. A method for photon counting based upon inner products comprising the steps of:
modulating an incident light field corresponding to an image by a series of patterns with a spatial light modulator;
optically computing inner products between the light field of said image and said series of patterns with an encoder;
recording the number of photons received for each pattern by photon counting; and
recovering the spatial distribution of the received photons based upon said inner products from said encoder;
wherein said recovering step is based on at least one of a Greedy reconstruction algorithm, Matching Pursuit, Orthogonal Matching Pursuit, Basis Pursuit, group testing, LASSO, LARS, expectation-maximization, Bayesian estimation algorithm, belief propagation, wavelet-structure exploiting algorithm, Sudocode reconstruction, reconstruction based on manifolds, l₁ reconstruction, l₀ reconstruction, and l₂ reconstruction.

7. A method for photon counting according to claim 6, where said spatial light modulator comprises a digital micromirror device.

8. A method for photon counting according to claim 6, wherein the step of recording further comprises recording the time of arrival of the received photons.

9. A method for photon counting according to claim 6, wherein the step of said photon detector provides time-correlated photon counts.

10. A method for photon counting according to claim 6, wherein the step of recovering further comprises recovering temporal information.

11. A method for decomposing an integrated temporal signature of arriving photons to a resolution finer than an integration time of a detector and is instead resolved to a temporal frame rate of a modulator.
